(19) United States
(12) Patent Application Publication
(10) Pub. No.: US 2025/0389789 A1
(43) Pub. Date: Dec. 25, 2025

(54) SHORT CIRCUIT DETERMINATION DEVICE, ELECTRONIC APPARATUS, AND SHORT CIRCUIT DETERMINATION METHOD

(71) Applicant: Mitsubishi Electric Corporation, Chiyoda-ku, Tokyo (JP)

(72) Inventor: Takahiro KUBOTA, Chiyoda-ku, Tokyo (JP)

(73) Assignee: Mitsubishi Electric Corporation, Chiyoda-ku, Tokyo (JP)

(21) Appl. No.: 18/879,568

(22) PCT Filed: Jul. 6, 2022
(86) PCT No.: PCT/JP2022/026821

§ 371 Date: Dec. 27, 2024

(51) Int. Cl. G01R 31/52; G01R 31/62

(52) U.S. Cl. CPC G01R 31/52; G01R 31/62

(57) ABSTRACT

A short circuit determining device includes a first current acquirer to acquire a first current value, which is a value of current flowing into a primary winding, and a second current acquirer to acquire a second current value, which is a value of current flowing from a secondary winding. The short circuit determining device further includes a short circuit determiner to determine whether a short circuit occurs in the secondary winding, on the basis of the first current value and a second current value referred to the primary side, or a first current value referred to the secondary side and the second current value, which are calculated from the first current value, the second current value, the number of turns of the primary winding, and the number of turns of the secondary winding.

### TECHNICAL FIELD

The present disclosure relates to a short circuit determining device, an electronic apparatus, and a method of determining a short circuit.

### BACKGROUND ART

Electric railway vehicles of an AC feeding system include a transformer that transforms the voltage of AC power fed from a substation via an overhead wire into a desired voltage value, and a power conversion apparatus that converts the AC power after voltage transformation by the transformer into desired AC power and feeds the converted AC power to a load device. Examples of such a transformer and a power conversion apparatus to be installed in an electric railway vehicle are disclosed in Patent Literature 1.

### CITATION LIST

### Patent Literature

Patent Literature 1: Unexamined Japanese Patent Application Publication No. H6-141404

### SUMMARY OF INVENTION

### Technical Problem

Patent Literature 1 discloses an electric vehicle control apparatus that includes a transformer, a power conversion device, and a protection circuit for protecting circuitry. The protection circuit includes means for detecting a circuit ground fault, which is connected to the ground terminal of the transformer and the connecting point between the converter and the inverter of the power conversion device. This means for detecting a circuit ground fault can detect a ground fault occurring at a position other than the predetermined ground point in the circuitry of the electric vehicle control apparatus, but cannot detect abnormalities, such as a short circuit in the secondary winding of the transformer, other than the ground fault.

An objective of the present disclosure, which has been accomplished in view of the above situations, is to provide a short circuit determining device, an electronic apparatus, and a method of determining a short circuit that can achieve determination of whether a short circuit occurs in a secondary winding of a transformer.

### Solution to Problem

In order to achieve the above objective, a short circuit determining device according to the present disclosure includes a first current acquirer, a second current acquirer, and a short circuit determiner. The first current acquirer acquires a first current value, which is a value of current flowing into a primary winding of a transformer. The transformer transforms a voltage of AC power fed to the primary winding and outputs the AC power after voltage transformation from one or more secondary windings of the transformer. The second current acquirer acquires a second current value, which is a value of current flowing from each of the one or more secondary windings. The short circuit determiner determines, based on the first current value and a second current value referred to a primary side, or a first current value referred to a secondary side and the second current value, whether a short circuit occurs in each of the one or more secondary windings. The second current value referred to the primary side and the first current value referred to the secondary side are calculated from the first current value, the second current value, the number of turns of the primary winding, and the number of turns of each of the one or more secondary windings.

### Advantageous Effects of Invention

The present disclosure can achieve determination of whether a short circuit occurs in the secondary winding, on the basis of the first current value and the second current value referred to the primary side, or the first current value referred to the secondary side and the second current value, which are calculated from the first current value, the second current value, the number of turns of the primary winding, and the number of turns of the secondary winding.

### BRIEF DESCRIPTION OF DRAWINGS

FIG. 1 is a block diagram illustrating a short circuit determining device and a power conversion apparatus according to Embodiment 1;

FIG. 2 illustrates an exemplary flow of current in the case of a short circuit in a secondary winding of a transformer in Embodiment 1;

FIG. 3 illustrates hardware components of the short circuit determining device according to Embodiment 1;

FIG. 4 is a flowchart illustrating a short circuit determining process executed by the short circuit determining device according to Embodiment 1;

FIG. 5 is a block diagram illustrating a short circuit determining device and a power conversion apparatus according to Embodiment 2;

FIG. 6 is a flowchart illustrating a short circuit determining process executed by the short circuit determining device according to Embodiment 2; and

FIG. 7 illustrates a modification of the hardware components of the short circuit determining device according to the embodiments.

### DESCRIPTION OF EMBODIMENTS

A short circuit determining device, an electronic apparatus, and a method of determining a short circuit according to some embodiments of the present disclosure are described in detail below, with reference to the accompanying drawings. In the drawings, the components identical or corresponding to each other are provided with the same reference symbol.

### Embodiment 1

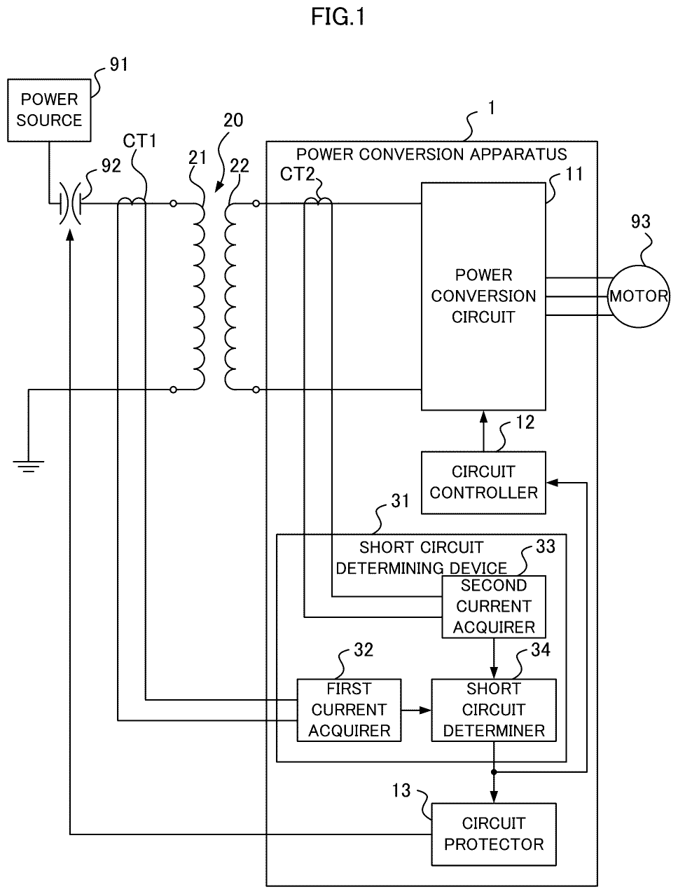

A typical example of an electronic apparatus installed in a railway vehicle is a power conversion apparatus installed in a railway vehicle to convert electric power fed from a power source into AC power to be fed to a load device and feed the converted AC power to a motor. A power conversion apparatus 1 illustrated in FIG. 1 is installed in a railway vehicle of an AC feeding system. The railway vehicle of an AC feeding system is provided with, as well as the power conversion apparatus 1, a transformer 20 that transforms the voltage of AC power fed from a power source 91 and feeds the AC power after voltage transformation to the power conversion apparatus 1.

The power conversion apparatus 1 converts the AC power, fed from the power source 91 via a circuit breaker 92 and transformed by the transformer 20, into AC power to be fed to a load device, specifically, a motor 93, and feeds the converted AC power to the motor 93. A typical example of the motor 93 is a three-phase induction motor for generating propulsion force of the railway vehicle. The power conversion apparatus 1 includes a short circuit determining device 31 that determines whether a short circuit occurs in the transformer 20. In response to a short circuit in the transformer 20, the power conversion apparatus 1 opens the circuit breaker 92 and thus electrically disconnects the transformer 20 from the power source 91.

The power source 91 is installed in the railway vehicle. A typical example of the power source 91 is a current collector that acquires AC power from the substation via a power supply line. The current collector is a pantograph or a contact shoe, for example. The power supply line is an overhead wire or a third rail, for example.

The electrical path between the power source 91 and the transformer 20 is provided with a circuit breaker 92 that electrically connects or disconnects the transformer 20 to or from the power source 91. The circuit breaker 92 is closed or opened by the power conversion apparatus 1 or a circuit breaker controller, which is not illustrated. The circuit breaker 92 when closed electrically connects the transformer 20 to the power source 91. The circuit breaker 92 when opened electrically disconnects the transformer 20 from the power source 91.

The transformer 20 includes a primary winding 21 electrically connected to the power source 91 via the circuit breaker 92, and a secondary winding 22 electrically connected to the electronic apparatus, specifically, the power conversion apparatus 1. The transformer 20 transforms the voltage of AC power fed from the power source 91 to the primary winding 21 via the circuit breaker 92, and outputs the AC power after voltage transformation from the secondary winding 22 to the power conversion apparatus 1.

One end of the primary winding 21 is electrically connected to the circuit breaker 92. The other end of the primary winding 21 is grounded via a component, such as ground ring, ground brush, or wheel, which is not illustrated.

One end of the secondary winding 22 is electrically connected to one of the primary terminals of a power conversion circuit 11 included in the power conversion apparatus 1. The other end of the secondary winding 22 is electrically connected to the other of the primary terminals of the power conversion circuit 11.

The power conversion apparatus 1 is electrically connected to the secondary winding 22. The power conversion apparatus 1 converts the AC power output from the secondary winding 22 into electric power to be fed to the load device, specifically, the motor 93, and feeds the converted electric power to the motor 93.

The power conversion apparatus 1 includes the power conversion circuit 11 of which the primary terminals are electrically connected to the secondary winding 22 and the secondary terminals are electrically connected to the motor 93, a circuit controller 12 that controls the power conversion circuit 11, the short circuit determining device 31 that determines whether a short circuit occurs in the secondary winding 22, and a circuit protector 13 that electrically disconnects the primary winding 21 from the power source 91 when a short circuit is determined to occur in the secondary winding 22.

The power conversion circuit 11 converts the AC power fed from the secondary winding 22 via the primary terminals into three-phase AC power to be fed to the motor 93, and then feeds the three-phase AC power from the secondary terminals to the motor 93. For example, the power conversion circuit 11 includes a converter that converts the AC power fed from the secondary winding 22 into DC power and outputs the DC power, a capacitor charged with the DC power output from the converter, and an inverter that converts the DC power fed from the converter via the capacitor into three-phase AC power.

Each of the converter and the inverter includes multiple switching elements, such as insulated gate bipolar transistors (IGBTs), gate turn-off thyristors (GTOs), or metal-oxide-semiconductor field-effect transistors (MOSFETs). The switching elements perform switching operations and thus allow the converter and the inverter to perform power conversion.

The circuit controller 12 controls the switching elements included in the power conversion circuit 11, in accordance with an operation command for the railway vehicle acquired from a cab, which is not illustrated, and a result of determination by the short circuit determining device 31. For example, the circuit controller 12 transmits pulse width modulation (PWM) signals to the individual gate terminals of the IGBTs of the converter and the inverter and thus controls the IGBTs.

During running of the railway vehicle, the circuit controller 12 controls the power conversion circuit 11 in accordance with an operation command. The circuit controller 12, when receiving a result of determination indicating the occurrence of a short circuit in the transformer 20 from the short circuit determining device 31, stops the power conversion circuit 11.

The circuit protector 13 controls the circuit breaker 92, in accordance with a result of determination by the short circuit determining device 31. In detail, the circuit protector 13 maintains the circuit breaker 92 to be closed, while the short circuit determining device 31 keeps determining that no short circuit occurs in the secondary winding 22. When the short circuit determining device 31 determines that a short circuit occurs in the secondary winding 22, the circuit protector 13 opens the circuit breaker 92 and electrically disconnects the primary winding 21 of the transformer 20 from the power source 91.

The short circuit determining device 31 includes a first current acquirer 32 that acquires a first current value, which is a value of current flowing into the primary winding 21, and a second current acquirer 33 that acquires a second current value, which is a value of current flowing from the secondary winding 22. The short circuit determining device 31 further includes a short circuit determiner 34 that determines whether a short circuit occurs in the secondary winding 22, on the basis of the first current value, the second current value, the number of turns of the primary winding 21, and the number of turns of the secondary winding 22.

The first current acquirer 32 measures a first current value, which is a value of current flowing in the electrical path between the power source 91 and the primary winding 21. In detail, the first current acquirer 32 measures a first current value, with a current-transformer (CT) type current sensor CT1 provided to the conductor that connects the circuit breaker 92 to the one end of the primary winding 21.

The second current acquirer 33 measures a second current value, which is a value of current flowing in the electrical path between the secondary winding 22 and the electronic apparatus, specifically, the power conversion apparatus 1. In detail, the second current acquirer 33 measures a second current value, with a CT type current sensor CT2 provided to the conductor that connects one end of the secondary winding 22 to one of the primary terminals of the power conversion circuit 11.

The short circuit determiner 34 determines whether a short circuit occurs in the secondary winding 22, on the basis of the first current value and a second current value referred to the primary side, or a first current value referred to the secondary side and the second current value, which are calculated from the first current value, the second current value, and the turn ratio of the transformer 20. The short circuit determiner 34 is assumed to preliminarily retain information on the turn ratio of the transformer 20.

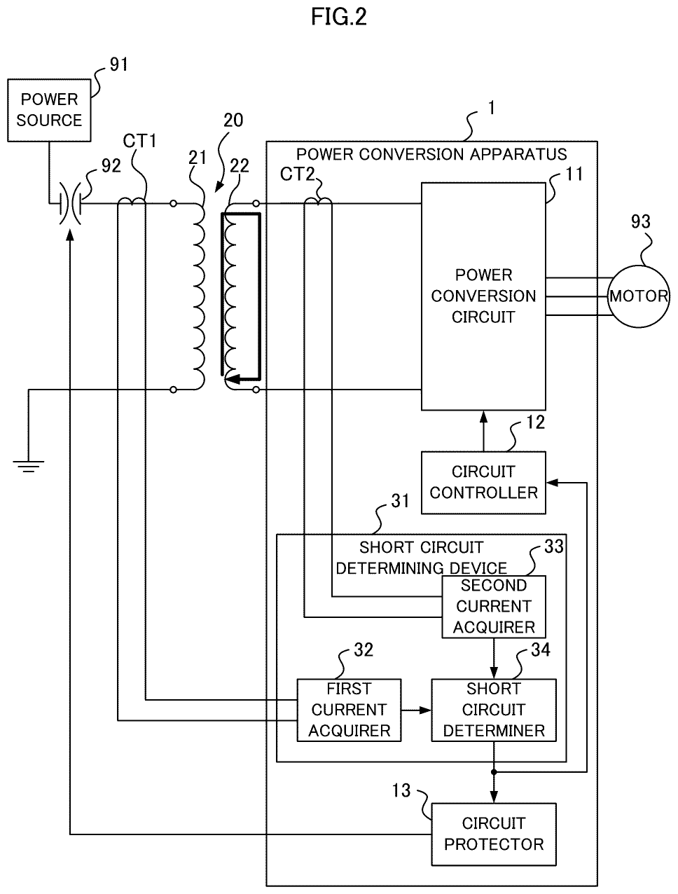

As an exemplary abnormality in the secondary winding 22, the conductor that connects the one end of the secondary winding 22 to the power conversion circuit 11 may be electrically connected directly to the conductor that connects the other end of the secondary winding 22 to the power conversion circuit 11, for example. This direct connection causes current to flow through a closed circuit defined through the secondary winding 22, for example, as illustrated by the solid-line arrow in FIG. 2. In the case of a short circuit at a position closer to the secondary winding 22 than the current sensor CT2, no current flows in the current sensor CT2, so that the second current value to be acquired by the second current acquirer 33 is sufficiently smaller than that in the case of no short circuit in the secondary winding 22.

Because of such a small second current value in the case of a short circuit in the secondary winding 22 described above, the short circuit determiner 34 in Embodiment 1 determines whether a short circuit occurs in the secondary winding 22, on the basis of the difference between the first current value and the second current value referred to the primary side, specifically, the current value on the primary side of the transformer 20 calculated from the second current value. When the absolute value of the difference between the first current value and the current value on the primary side of the transformer 20 calculated from the second current value is at least a first threshold, a short circuit is deemed to occur in the secondary winding 22. In contrast, when the absolute value of the difference between the first current value and the current value on the primary side of the transformer 20 calculated from the second current value is smaller than the first threshold, no short circuit is deemed to occur in the secondary winding 22. The first threshold is defined in accordance with a possible range of amplitude of current flowing into the primary winding 21. For example, the first threshold is a value calculated by multiplying the lower limit of the possible range of amplitude of current flowing into the primary winding 21 by a positive coefficient smaller than 1, for example, 0.5. The short circuit determiner 34 is assumed to preliminarily retain information on the first threshold.

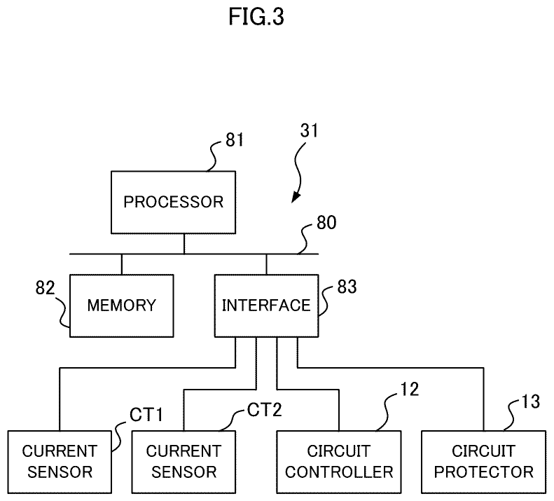

FIG. 3 illustrates hardware components of the short circuit determining device 31 having the above-described configuration. The short circuit determining device 31 includes a processor 81, a memory 82, and an interface 83. The processor 81, the memory 82, and the interface 83 are connected to each other via buses 80. The functions of the short circuit determining device 31 are implemented by software, firmware, or a combination of software and firmware. The software and firmware are described in the form of programs, and stored in the memory 82. The processor 81 reads and executes the programs stored in the memory 82, and thus achieves the above-described functions of the components. In other words, the memory 82 stores programs for executing the processing of the components of the short circuit determining device 31.

Examples of the memory 82 include non-volatile or volatile semiconductor memories, such as random access memory (RAM), read-only memory (ROM), flash memory, erasable programmable read-only memory (EPROM), and electrically erasable and programmable read-only memory (EEPROM), magnetic disks, flexible disks, optical disks, compact discs, mini discs, and digital versatile discs (DVDs).

The short circuit determining device 31 is connected to the current sensors CT1 and CT2, the circuit controller 12, and the circuit protector 13 via the interface 83. The interface 83 includes interface modules compliant with one or more standards as appropriate for connection destinations.

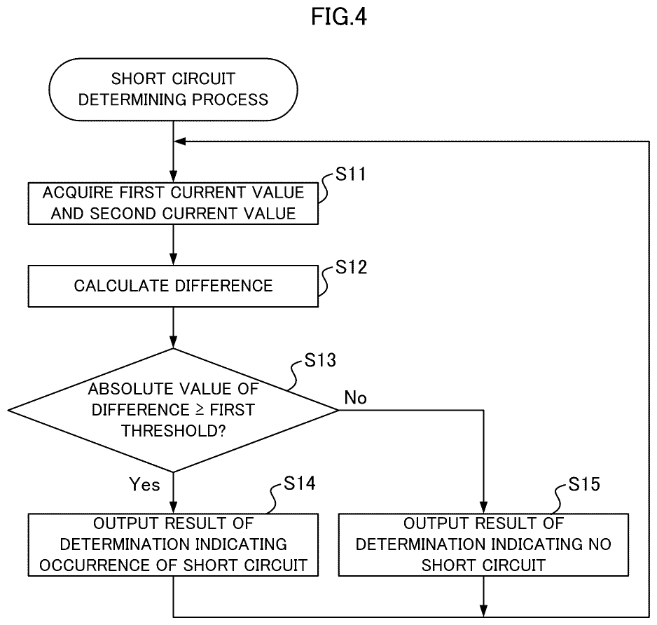

The short circuit determining device 31 having the above-described configuration executes a short circuit determining process, which is described below with reference to FIG. 4. In response to start of running of the railway vehicle and closing of the circuit breaker 92, the short circuit determining device 31 initiates the process illustrated in FIG. 4.

The first current acquirer 32 acquires a first current value, which is a value of current flowing into the primary winding 21, and the second current acquirer 33 acquires a second current value, which is a value of current flowing from the secondary winding 22 (Step S11).

The short circuit determiner 34 calculates a difference ΔD1 between the first current value I_{P} and the current value on the primary side of the transformer 20 calculated from the second current value I_{S1}, using Expression (1) below (Step S12). In detail, the short circuit determiner 34 subtracts the product of the second current value I_{S1} and the inverse of the turn ratio N_{P}/N_{S1} of the transformer 20, from the first current value I_{P}, and thus calculates a difference ΔD1.

$$\begin{matrix}Expression 1 & \\ Δ D 1 = {I}_{P} - {I}_{S 1} \cdot \frac{{N}_{S 1}}{{N}_{P}} & ( 1 )\end{matrix}$$

The short circuit determiner 34 determines whether the absolute value of the difference ΔD1 calculated in Step S12 is at least the first threshold (Step S13). When the absolute value of the difference ΔD1 calculated in Step S12 is at least the first threshold (Step S13; Yes), the short circuit determiner 34 outputs a result of determination indicating the occurrence of a short circuit, to the circuit controller 12 and the circuit protector 13 (Step S14). In response to this result, the circuit controller 12 stops the power conversion circuit 11, and the circuit protector 13 opens the circuit breaker 92. This operations causes the transformer 20, of which the secondary winding 22 has a short circuit, to be electrically disconnected from the power source 91. After Step S14, the short circuit determining device 31 repeats Step S11 and the subsequent steps described above.

In contrast, when the absolute value of the difference ΔD1 calculated in Step S12 is smaller than the first threshold (Step S13; No), the short circuit determiner 34 outputs a result of determination indicating no short circuit, to the circuit controller 12 and the circuit protector 13 (Step S15). In response to this result, the circuit controller 12 continues to operate the power conversion circuit 11 in accordance with an operation command. The circuit protector 13 does not open the circuit breaker 92, and maintains the circuit breaker 92 to be closed. After Step S15, the short circuit determining device 31 repeats Step S11 and the subsequent steps described above.

As described above, the short circuit determining device 31 according to Embodiment 1 can determine whether a short circuit occurs in the secondary winding 22 of the transformer 20, on the basis of the first current value and the second current value referred to the primary side, which are calculated from the first current value, the second current value, and the turn ratio of the transformer 20.

### Embodiment 2

The configuration of the transformer 20 in Embodiment 1 is a mere example. The transformer 20 may include multiple secondary windings, for example. The configuration of the short circuit determining device 31 in Embodiment 1 is a mere example. The short circuit determining device 31 may open the circuit breaker 92. The description of Embodiment 2 demonstrates the transformer 20 and the short circuit determining device 31 having a configuration different from that in Embodiment 1, focusing on the differences from Embodiment 1.

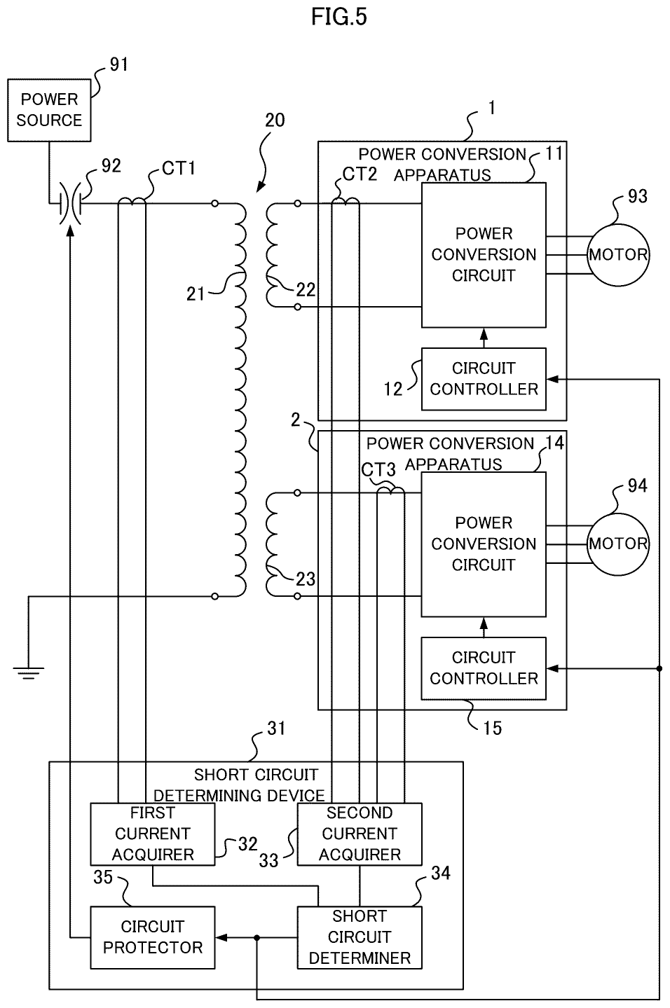

As illustrated in FIG. 5, the transformer 20 in Embodiment 2 includes a primary winding 21, and multiple secondary windings, specifically, secondary windings 22 and 23. The secondary winding 22 is electrically connected to a power conversion apparatus 1, as in Embodiment 1. The secondary winding 23 is electrically connected to a power conversion apparatus 2. The transformer 20 transforms the voltage of AC power fed from the power source 91 to the primary winding 21 via the circuit breaker 92, and outputs the AC power after voltage transformation from the secondary winding 22 to the power conversion apparatus 1, and outputs the AC power after voltage transformation from the secondary winding 23 to the power conversion apparatus 2.

The power conversion apparatus 2 converts the AC power, fed from the power source 91 via the circuit breaker 92 and transformed by the transformer 20, into AC power to be fed to a load device, specifically, a motor 94, and feeds the converted AC power to the motor 94. A typical example of the motor 94 is a three-phase induction motor for generating propulsion force of the railway vehicle.

The power conversion apparatus 2 includes a power conversion circuit 14 of which the primary terminals are electrically connected to the secondary winding 23 and the secondary terminals are electrically connected to the motor 94, and a circuit controller 15 that controls the power conversion circuit 14.

The power conversion circuit 14 converts the AC power fed from the secondary winding 23 via the primary terminals into three-phase AC power to be fed to the motor 94, and then feeds the three-phase AC power from the secondary terminals to the motor 94. For example, the power conversion circuit 14 includes a converter that converts the AC power fed from the secondary winding 23 into DC power and outputs the DC power, a capacitor charged with the DC power output from the converter, and an inverter that converts the DC power fed from the converter via the capacitor into three-phase AC power.

Each of the converter and the inverter includes multiple switching elements, such as IGBTs, GTOs, or MOSFETs. The switching elements perform switching operations and thus allow the converter and the inverter to perform power conversion.

The circuit controller 15 controls the switching elements included in the power conversion circuit 14, in accordance with an operation command for the railway vehicle acquired from the cab and a result of determination by the short circuit determining device 31. For example, the circuit controller 15 transmits PWM signals to the individual gate terminals of the IGBTs of the converter and the inverter and thus controls the IGBTs.

During running of the railway vehicle, the circuit controller 15 controls the power conversion circuit 14 in accordance with an operation command. The circuit controller 15, when receiving a result of determination indicating the occurrence of a short circuit in the transformer 20 from the short circuit determining device 31, stops the power conversion circuit 14.

The power conversion apparatuses 1 and 2 both exclude the short circuit determining device 31 and the circuit protector 13, unlike the power conversion apparatus 1 according to Embodiment 1.

In Embodiment 2, the short circuit determining device 31 is an independent device separate from the power conversion apparatuses 1 and 2. The second current acquirer 33 of the short circuit determining device 31 acquires second current values, which are values of current flowing from the respective secondary windings 22 and 23. In other words, the second current acquirer 33 measures a second current value of the secondary winding 22, which is a value of current flowing in the electrical path between the secondary winding 22 and the power conversion circuit 11, and a second current value of the secondary winding 23, which is a value of current flowing in the electrical path between the secondary winding 23 and the power conversion circuit 14.

In detail, the second current acquirer 33 measures second current values of the secondary windings 22 and 23, with a CT type current sensor CT2 provided to the conductor that connects one end of the secondary winding 22 to one of the primary terminals of the power conversion circuit 11, and a CT type current sensor CT3 provided to the conductor that connects one end of the secondary winding 23 to one of the primary terminals of the power conversion circuit 14.

The short circuit determiner 34 determines whether a short circuit occurs in the secondary windings 22 and 23, on the basis of the first current value and second current values referred to the primary side, which are calculated from the first current value, the second current value, the number of turns of the primary winding 21, and the numbers of turns of the respective secondary windings 22 and 23. The short circuit determiner 34 is assumed to preliminarily retain information on the number of turns of the primary winding 21 and the numbers of turns of the respective secondary windings 22 and 23.

As an exemplary abnormality, a short circuit may occur in at least either of the secondary windings 22 and 23. For example, a short circuit may occur in the secondary winding 22, specifically, the conductor that connects the one end of the secondary winding 22 to the one of the primary terminals of the power conversion circuit 11 may be electrically connected directly to the conductor that connects the other end of the secondary winding 22 to the other of the primary terminals of the power conversion circuit 11. This direct connection causes current to flow through a closed circuit defined through the secondary winding 22. In the case of a short circuit at a position closer to the secondary winding 22 than the current sensor CT2, no current flows in the current sensor CT2, so that the second current value of the secondary winding 22 to be acquired by the second current acquirer 33 is sufficiently smaller than that in the case of no short circuit in the secondary winding 22.

For another example, a short circuit may occur in the secondary winding 23, specifically, the conductor that connects the one end of the secondary winding 23 to the power conversion circuit 14 may be electrically connected directly to the conductor that connects the other end of the secondary winding 23 to the power conversion circuit 14. This direct connection causes current to flow through a closed circuit defined through the secondary winding 23. In the case of a short circuit at a position closer to the secondary winding 23 than the current sensor CT3, no current flows in the current sensor CT3, so that the second current value of the secondary winding 23 to be acquired by the second current acquirer 33 is sufficiently smaller than that in the case of no short circuit in the secondary winding 23.

Because of such a small sum of second current values in the case of a short circuit in at least either of the secondary windings 22 and 23 described above, the short circuit determiner 34 determines whether a short circuit occurs in at least either of the secondary windings 22 and 23, on the basis of the difference between the first current value and the second current values referred to the primary side, specifically, current values on the primary side of the transformer 20 calculated from the second current values. When the absolute value of the difference between the first current value and the current value on the primary side of the transformer 20 calculated from the second current values is at least the first threshold, a short circuit is deemed to occur in at least either of the secondary windings 22 and 23. In contrast, when the absolute value of the difference between the first current value and the current value on the primary side of the transformer 20 calculated from the second current values is smaller than the first threshold, no short circuit is deemed to occur in the secondary windings 22 and 23.

The short circuit determining device 31 also includes, in addition to the components of the short circuit determining device 31 according to Embodiment 1, a circuit protector 35 that controls the circuit breaker 92. The circuit protector 35 closes or opens the circuit breaker 92, in accordance with a result of determination by the short circuit determiner 34. In detail, the circuit protector 35 maintains the circuit breaker 92 to be closed, while the short circuit determiner 34 keeps determining that no short circuit occurs in the secondary windings 22 and 23. When the short circuit determiner 34 determines that a short circuit occurs in at least either of the secondary windings 22 and 23, the circuit protector 35 opens the circuit breaker 92 and electrically disconnects the primary winding 21 of the transformer 20 from the power source 91.

The short circuit determining device 31 has the hardware components identical to those in Embodiment 1, except for the connection destinations via the interface 83. In Embodiment 2, the interface 83 is connected to the current sensors CT1, CT2, and CT3 and the circuit controllers 12 and 15.

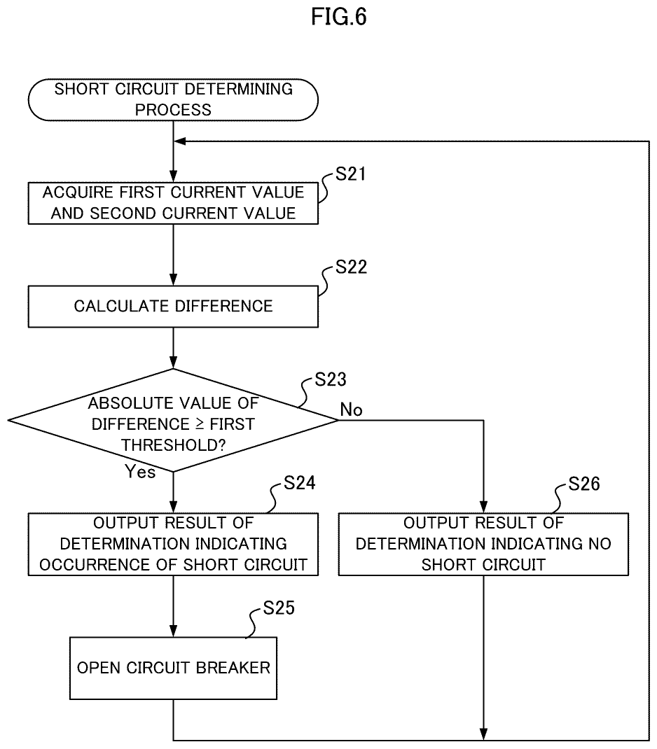

The short circuit determining device 31 having the above-described configuration executes a short circuit determining process, which is described below with reference to FIG. 6. In response to start of running of the railway vehicle and closing of the circuit breaker 92, the short circuit determining device 31 initiates the process illustrated in FIG. 6.

The first current acquirer 32 acquires a first current value, which is a value of current flowing into the primary winding 21, and the second current acquirer 33 acquires second current values, which are values of current flowing from the respective secondary windings 22 and 23 (Step S21).

The short circuit determiner 34 calculates a difference ΔD2 between the first current value and the current value on the primary side of the transformer 20 calculated from the second current value, using the Expression (2) below (Step S22). In detail, the short circuit determiner 34 subtracts the sum of the second current value I_{S1} multiplied by the number N_{S1} of turns of the secondary winding 22 and divided by the number N_{P} of turns of the primary winding 21 and the second current value I_{S2} multiplied by the number of turns N_{S2} of the secondary winding 23 and divided by the number N_{P} of turns of the primary winding 21, from the first current value I_{P}, and thus calculates a difference ΔD2. The second current value I_{S1} indicates a value of current flowing from the secondary winding 22, and the second current value I_{S2} indicates a value of current flowing from the secondary winding 23.

$$\begin{matrix}Expression 2 & \\ Δ D 2 = {I}_{P} - ( {I}_{S 1} \cdot \frac{{N}_{S 1}}{{N}_{P}} + {I}_{S 2} \cdot \frac{{N}_{S 2}}{{N}_{P}} ) & ( 2 )\end{matrix}$$

The short circuit determiner 34 determines whether the absolute value of the difference ΔD2 calculated in Step S22 is at least the first threshold (Step S23). When the absolute value of the difference ΔD2 calculated in Step S22 is at least the first threshold (Step S23; Yes), the short circuit determiner 34 outputs a result of determination indicating the occurrence of a short circuit, to the circuit controllers 12 and and the circuit protector 35 (Step S24). In response to this result, the circuit controllers 12 and 15 stop the power conversion circuits 11 and 14.

The circuit protector 35, when receiving a result of determination indicating the occurrence of a short circuit, opens the circuit breaker 92 (Step S25). After Step S25, the short circuit determining device 31 repeats Step S21 and the subsequent steps described above.

In contrast, when the absolute value of the difference ΔD2 calculated in Step S22 is smaller than the first threshold (Step S23; No), the short circuit determiner 34 outputs a result of determination indicating no short circuit, to the circuit controllers 12 and 15 and the circuit protector 35 (Step S26). In response to this result, the circuit controllers 12 and 15 continue to operate the power conversion circuits 11 and 14 in accordance with an operation command. The circuit protector 35 skips Step S25, specifically, does not open the circuit breaker 92, and maintains the circuit breaker 92 to be closed. After Step S26, the short circuit determining device 31 repeats Step S21 and the subsequent steps described above.

As described above, the short circuit determining device 31 according to Embodiment 2 can determine whether a short circuit occurs in the secondary windings 22 and 23, on the basis of the first current value, the second current value, the number of turns of the primary winding 21, and the numbers of turns of the respective secondary windings 22 and 23, and can electrically disconnect the transformer 20 from the power source 91 in the case of a short circuit in the secondary winding 22 or 23.

The above-described embodiments of the present disclosure are mere examples. The power conversion apparatuses 1 and 2 can be installed in any vehicle or apparatus in which the power conversion apparatuses 1 and 2 are fed with electric power. The power conversion apparatuses 1 and 2 can also be installed in vehicles, such as diesel vehicles, other than the electric railway vehicle.

The transformer 20 may have a configuration other than that in the above-described examples. The transformer 20 may include any number of secondary windings. The secondary windings included in the transformer 20 may have the same number of turns or different number of turns.

The short circuit determining process executed by the short circuit determiner 34 may be a process other than those in the above-described examples. For example, the short circuit determiner 34 may determine whether a short circuit occurs in the secondary winding 22, on the basis of a first current value referred to the secondary side and the second current value. In detail, the short circuit determiner 34 may calculate a difference ΔD1′ between a current value on the secondary side of the transformer 20 calculated from the first current value I_{P} and the second current value I_{S1}, using Expression (3) below. In detail, the short circuit determiner 34 may subtract the second current value I_{S1} from the product of the first current value I_{P} and the turn ratio N_{P}/N_{S1} of the transformer 20, and thus calculate a difference ΔD1′.

$$\begin{matrix}Expression 3 & \\ Δ D {1}^{′} = {I}_{P} \cdot \frac{{N}_{P}}{{N}_{S 1}} - {I}_{S 1} & ( 3 )\end{matrix}$$

In this case, the short circuit determiner 34 determines whether the absolute value of the difference ΔD1′ is at least a second threshold. The second threshold is defined in accordance with a possible range of amplitude of current flowing from the secondary winding 22. For example, the second threshold is a value calculated by multiplying the lower limit of the possible range of amplitude of current flowing from the secondary winding 22 by a positive coefficient smaller than 1, for example, 0.5. The short circuit determiner 34 is assumed to preliminarily retain information on the second threshold.

In another exemplary case where multiple secondary windings included in the transformer 20 have the same number of turns, the short circuit determiner 34 of the short circuit determining device 31 according to Embodiment 2 may determine whether a short circuit occurs in each of the secondary windings, on the basis of the first current value, the second current value, the number of turns of the primary winding 21, and the number of turns of the secondary winding.

In detail, the short circuit determiner 34 calculates a difference ΔD3 between the first current value and a current value on the primary side of the transformer 20 calculated from each of the second current values, using Expression (4) below. In Expression (4) below, M indicates the number of secondary windings included in the transformer 20, and N_{S} indicates the number of turns of the secondary winding. k indicates a natural number equal to or larger than 1 and equal to or smaller than M, and I_{Sk} indicates a second current value, which is a value of current flowing from each of the secondary windings.

$$\begin{matrix}Expression 4 & \\ Δ D 3 = {I}_{P} - {I}_{Sk} \cdot \frac{{N}_{S}}{{N}_{P}} \cdot M & ( 4 )\end{matrix}$$

The short circuit determiner 34 calculates a difference ΔD3 for each of the secondary windings, and determines whether the absolute value of the difference ΔD3 is at least the first threshold. When the absolute value of the difference ΔD3 is at least the first threshold in either of the secondary windings, a short circuit is deemed to occur in this secondary winding.

Alternatively, the short circuit determiner 34, when determining that a short circuit occurs in at least any of the secondary windings, may determine whether a short circuit occurs in each of the secondary windings, on the basis of the second current values of the secondary windings. Specifically, the short circuit determiner 34 may determine whether the second current value of each of the secondary windings has an amplitude falling within a range of values sufficiently low to be deemed 0. In the case of a short circuit, a current value detectable by a current sensor is sufficiently small, as described above. The short circuit determiner 34 thus determines whether a short circuit occurs in each of the secondary windings, on the basis of whether the second current value of each of the secondary windings has an amplitude falling within a range of values sufficiently low to be deemed 0.

Alternatively, the short circuit determiner 34 may determine whether a short circuit occurs in the secondary winding, on the basis of the ratio of the second current value referred to the primary side to the original first current value, or the ratio of the first current value referred to the secondary side to the original second current value. Specifically, the short circuit determiner 34 may determine whether a short circuit occurs in the secondary winding 22, on the basis of the ratio of the current value on the primary side of the transformer 20 calculated from the second current value to the first current value. When the absolute value of the ratio of the current value on the primary side of the transformer 20 calculated from the second current value to the first current value is equal to or smaller than a third threshold, a short circuit is deemed to occur in the secondary winding 22. The third threshold is a positive value smaller than 1, for example, 0.5. The short circuit determiner 34 is assumed to preliminarily retain information on the third threshold.

Alternatively, the short circuit determiner 34 may determine whether a short circuit occurs in the secondary winding 22, on the basis of the ratio of the current value on the secondary side of the transformer 20 calculated from the first current value to the second current value. When the ratio of the current value on the secondary side of the transformer 20 calculated from the first current value to the second current value is equal to or smaller than the third threshold, a short circuit is deemed to occur in the secondary winding 22.

The electronic apparatus connected to the transformer 20 is not necessarily the power conversion apparatus 1 or 2 and may be any electronic apparatus.

The power conversion apparatuses 1 and 2 may feed electric power to any load device, such as lighting equipment or air conditioner, other than the motors 93 and 94.

The current sensors CT1, CT2, and CT3 may be disposed at positions other than those in the above-described examples. For example, the current sensor CT1 may be provided to the conductor connected to the other end of the primary winding 21. The current sensor CT2 may be provided to the conductor that connects the other end of the secondary winding 22 to the other of the primary terminals of the power conversion circuit 11. The current sensor CT3 may be provided to the conductor that connects the other end of the secondary winding 23 to the power conversion circuit 14.

The first current acquirer 32 may obtain an amplitude of current flowing into the primary winding 21 from the measured value of current flowing into the primary winding 21, and use this amplitude as a first current value.

The second current acquirer 33 may obtain an amplitude of current flowing from the secondary winding 22 from the measured value of current flowing from the secondary winding 22, and use this amplitude as a second current value of the secondary winding 22. The second current acquirer 33 may obtain an amplitude of current flowing from the secondary winding 23 from the measured value of current flowing from the secondary winding 23, and use this amplitude as a second current value of the secondary winding 23.

Although the circuit protector 13 is included in the power conversion apparatus 1 in Embodiment 1, the circuit protector 13 may also be achieved as a function of an integrated train control and monitoring device.

Although the short circuit determining device 31 is separate from the power conversion apparatuses 1 and 2 in Embodiment 2, the short circuit determining device 31 may also be included in the power conversion apparatus 1 or 2. Alternatively, the short circuit determining device 31 may be achieved as a function of the train control and monitoring device.

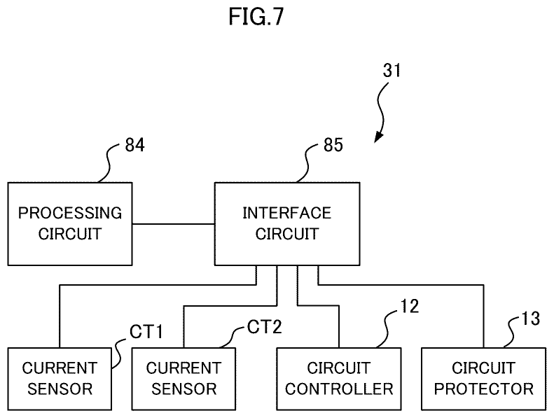

The short circuit determining device 31 may have hardware components other than those in the above-described examples. The short circuit determining device 31 may be achieved by a processing circuit 84, as illustrated in FIG. 7. The processing circuit 84 is connected to the current sensors CT1 and CT2, the circuit controller 12, and the circuit protector 13, via an interface circuit 85.

In the case where the processing circuit 84 is dedicated hardware, the processing circuit 84 includes a single circuit, a combined circuit, a processor, an application specific integrated circuit (ASIC), a field programmable gate array (FPGA), or a combination thereof, for example. The individual components of the short circuit determining device 31 may be achieved by separate processing circuits 84 or by the same processing circuit 84.

A part of the functions of the short circuit determining device 31 may be performed by dedicated hardware, whereas another part of the functions may be performed by software or firmware. For example, the first current acquirer 32 and the second current acquirer 33 may be achieved by the processing circuit 84 illustrated in FIG. 7, whereas the short circuit determiner 34 may be achieved by programs stored in the memory 82 when the programs are read and executed by the processor 81 illustrated in FIG. 3, in the short circuit determining device 31 according to Embodiment 1.

The foregoing describes some example embodiments for explanatory purposes. Although the foregoing discussion has presented specific embodiments, persons skilled in the art will recognize that changes may be made in form and detail without departing from the broader spirit and scope of the invention. Accordingly, the specification and drawings are to be regarded in an illustrative rather than a restrictive sense. This detailed description, therefore, is not to be taken in a limiting sense, and the scope of the invention is defined only by the included claims, along with the full range of equivalents to which such claims are entitled.

### REFERENCE SIGNS LIST

1, 2 Power conversion apparatus
11, 14 Power conversion circuit
12, 15 Circuit controller
13, 35 Circuit protector
20 Transformer
21 Primary winding
22, 23 Secondary winding
31 Short circuit determining device
32 First current acquirer
33 Second current acquirer
34 Short circuit determiner
80 Bus
81 Processor
82 Memory
83 Interface
84 Processing circuit
85 Interface circuit
91 Power source
92 Circuit breaker
93, 94 Motor
CT1, CT2, CT3 Current sensor

1. A short circuit determining device, comprising:
first current acquiring circuitry to acquire a first current value, the first current value being a value of current flowing into a primary winding of a transformer, the transformer transforming a voltage of AC power fed to the primary winding and outputting the AC power after voltage transformation from a plurality of secondary windings of the transformer;
second current acquiring circuitry to acquire second current values, the second current values being a values of current flowing from the plurality of secondary windings; and
short circuit determining circuitry to determine, based on the first current value and second current values referred to a primary side, whether a short circuit occurs in at least any of the plurality of secondary windings, the second current values referred to the primary side being calculated from the first current value, the second current values of the plurality of secondary windings, a number of turns of the primary winding, and numbers of turns of the plurality of secondary windings, wherein
when the short circuit determining circuitry determines that a short circuit occurs in at least any of the plurality of secondary windings, the short circuit determining circuitry determines, based on the second current values of the plurality of secondary windings, whether a short circuit occurs in each of the plurality of secondary windings.

2. The short circuit determining device according to claim 1, wherein the first current acquiring circuitry measures the first current value, the first current value being a value of current flowing in an electrical path between a power source and the primary winding, the power source feeding electric power to the transformer.

3. The short circuit determining device according to claim 1, wherein the second current acquiring circuitry measures the second current values, the second current values being values of current flowing in electrical paths between the plurality of secondary windings and corresponding electronic apparatuses electrically connected to the plurality of secondary windings.

4-6. (canceled)

7. A short circuit determining device, comprising:
first current acquiring circuitry to acquire a first current value, the first current value being a value of current flowing into a primary winding of a transformer, the transformer transforming a voltage of AC power fed to the primary winding and outputting the AC power after voltage transformation from a plurality of secondary windings of the transformer, the plurality of secondary windings each having a same number of turns;
second current acquiring circuitry to acquire second current values, the second current values being values of current flowing from the plurality of secondary windings; and
short circuit determining circuitry to determine, for each of the plurality of secondary windings, based on the first current value and second current values referred to a primary side, or a first current value referred to a secondary side and the second current values, whether a short circuit occurs in at least any of the plurality of secondary windings, the second current values referred to the primary side and the first current value referred to the secondary side being calculated from the first current value, the second current value of each of the plurality of secondary windings, a number of turns of the primary winding, and a number of turns of each of the plurality of secondary windings.

8-14. (canceled)

15. The short circuit determining device according to claim 7, wherein the first current acquiring circuitry measures the first current value, the first current value being a value of current flowing in an electrical path between a power source and the primary winding, the power source feeding electric power to the transformer.

16. The short circuit determining device according to claim 7, wherein the second current acquiring circuitry measures the second current values, the second current values being values of current flowing in electrical paths between the plurality of secondary windings and corresponding electronic apparatuses electrically connected to the plurality of secondary windings.

17. The short circuit determining device according to claim 1, further comprising:
circuit protecting circuitry to electrically disconnect the primary winding from a power source when the short circuit determining circuitry determines that a short circuit occurs, the power source feeding electric power to the primary winding of the transformer.

18. The short circuit determining device according to claim 7, further comprising:
circuit protecting circuitry to electrically disconnect the primary winding from a power source when the short circuit determining circuitry determines that a short circuit occurs, the power source feeding electric power to the primary winding of the transformer.

19. An electronic apparatus electrically connected to any of a plurality of secondary windings of a transformer, the transformer transforming a voltage of AC power fed to a primary winding of the transformer and outputting the AC power after voltage transformation from the plurality of secondary windings, the electronic apparatus comprising:
the short circuit determining device according to claim 1 to determine whether a short circuit occurs in at least any of the plurality of secondary windings of the transformer.

20. An electronic apparatus electrically connected to any of a plurality of secondary windings of a transformer, the transformer transforming a voltage of AC power fed to a primary winding of the transformer and outputting the AC power after voltage transformation from the plurality of secondary windings, the electronic apparatus comprising:
the short circuit determining device according to claim 7 to determine whether a short circuit occurs in at least any of the plurality of secondary windings of the transformer.

21. The electronic apparatus according to claim 19, further comprising:
circuit protecting circuitry to electrically disconnect the primary winding from a power source when the short circuit determining circuitry determines that a short circuit occurs, the power source feeding electric power to the primary winding of the transformer.

22. The electronic apparatus according to claim 20, further comprising:
circuit protecting circuitry to electrically disconnect the primary winding from a power source when the short circuit determining circuitry determines that a short circuit occurs, the power source feeding electric power to the primary winding of the transformer.

23. An electronic apparatus, electrically connected to any of a plurality of secondary windings of a transformer, the transformer transforming a voltage of AC power fed to a primary winding of the transformer and outputting the AC power after voltage transformation from the plurality of secondary windings, the electronic apparatus comprising:
the short circuit determining device according to claim 17 to determine whether a short circuit occurs in at least any of the plurality of secondary windings of the transformer.

24. An electronic apparatus, electrically connected to any of a plurality of secondary windings of a transformer, the transformer transforming a voltage of AC power fed to a primary winding of the transformer and outputting the AC power after voltage transformation from the plurality of secondary windings, the electronic apparatus comprising:
the short circuit determining device according to claim 18 to determine whether a short circuit occurs in at least any of the plurality of secondary windings of the transformer.

25. The electronic apparatus according to claim 19, further comprising:
a power conversion circuit electrically connected to any of the plurality of secondary windings of the transformer, the power conversion circuit being configured to convert the AC power output from the connected one of the plurality of secondary windings into electric power to be fed to a load device, and output the converted electric power to the load device.

26. The electronic apparatus according to claim 20, further comprising:
a power conversion circuit electrically connected to any of the plurality of secondary windings of the transformer, the power conversion circuit being configured to convert the AC power output from the connected one of the plurality of secondary windings into electric power to be fed to a load device, and output the converted electric power to the load device.

27. The electronic apparatus according to claim 25, further comprising:
circuit controlling circuitry configured to control the power conversion circuit, wherein
the circuit controlling circuitry stops the power conversion circuit, when the short circuit determining circuitry determines that a short circuit occurs.

28. The electronic apparatus according to claim 26, further comprising:
circuit controlling circuitry configured to control the power conversion circuit, wherein
the circuit controlling circuitry stops the power conversion circuit, when the short circuit determining circuitry determines that a short circuit occurs.

29. A method of determining a short circuit, the method comprising:
acquiring a first current value, the first current value being a value of current flowing into a primary winding of a transformer, the transformer transforming a voltage of AC power fed to the primary winding and outputting the AC power after voltage transformation from a plurality of secondary windings of the transformer;
acquiring second current values, the second current values being values of current flowing from the plurality of secondary windings;
determining, based on the first current value and second current values referred to a primary side, whether a short circuit occurs in at least any of the plurality of secondary windings, the second current values referred to the primary side being calculated from the first current value, the second current values of the plurality of secondary windings, a number of turns of the primary winding, and numbers of turns of the plurality of secondary windings, and
upon determining that a short circuit occurs in at least any of the plurality of secondary windings, determining, based on the second current values of the plurality of secondary windings, whether a short circuit occurs in each of the plurality of secondary windings.
